(19) United States
(12) Patent Application Publication
(10) Pub. No.: US 2008/0054302 A1
(43) Pub. Date: Mar. 6, 2008

(54) FIELD EFFECT TRANSISTOR AND METHOD OF MANUFACTURING THE SAME

(75) Inventor: Akira FUJIHARA, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kanagawa (JP)

(21) Appl. No.: 11/844,947

(22) Filed: Aug. 24, 2007

(30) Foreign Application Priority Data
Aug. 31, 2006 (JP) 236509/2006

(51) Int. Cl. H01L 29/778; H01L 21/338

(52) U.S. Cl. 257/192; 438/172; 257/E29.246; 257/E21.451

(57) ABSTRACT

Disclosed is a field effect transistor including: an electron supplying layer made of AlGaAs; an interface stabilizing layer, provided on the electron supplying layer, and not containing Al; an etching stop layer, provided on the interface stabilizing layer, and made of TnGaP; and a contact layer, provided on the etching stop layer, and made of GaAs. This prevents a interfacial layer such as an AlGaAsP layer from being formed in the interface between the AlGaAs electron supplying layer and the InGaP etching stop layer, and prevents deterioration in the Schottky characteristic.

### BACKGROUND OF THE INVENTION

1. Field of the Invention

The present invention relates to a field effect transistor (FET) and a method of manufacturing the same.

2. Description of Related Art

GaAs heterojunction FETs (Field Effect Transistors) each with a recessed portion are widely used as transistors which operate with a high frequency band of several GHz to tens of GHz. In the case of this type of transistors, the depth of the recessed portion is an important parameter for enhancing or affecting characteristics including a threshold voltage and the like. There has been a reported case that the recessed portion was formed by dry etching techniques with a better controllability. Depending on intended use of the product, the gate electrode needs to be formed by evaporation and lift-off. In this case, the dry etching techniques are not applicable, so that the recessed portion needs to be formed by wet etching techniques. A method widely used in such cases is that of inserting an InGaP etching stop layer between a GaAs contact layer and an AlGaAs electron supplying layer (disclosed, for example, in Japanese Unexamined Patent Application Publication No. Hei. 7-335867 (hereinafter referred to as “Patent Document 1”)).

FIG. 1 is a cross-sectional view showing a GaAs heterojunction FET described in Patent Document 1. In an FET 100, a buffer semiconductor layer 102, an AlGaAs electron supplying layer 103, a channel layer 104, an AlGsAs electron supplying layer 105, an InGaP etching stop layer 106 and a GaAs contact layer 107 are sequentially formed on a semi-insulating GaAs substrate 101. In other words, the InGaP etching stop layer 106 is provided between the AlGaAs electron supplying layer 105 and the GaAs contact layer 107.

In addition, a recessed portion is formed by removing parts of each of the GaAs contact layer 107 and the InGaP etching stop layer 106. A gate electrode 109 is formed on the AlGaAs electron supplying layer 105 inside the recessed portion. As described above, a source/drain electrode 108 is formed on the GaAs contact layer 107 for the purpose of reducing its contact resistance, whereas the gate electrode 109 is formed on the AlGaAs electron supplying layer 105 for the purpose of securing a better Schottky characteristic.

The FET 100 with such a configuration is manufactured as follows. First of all, the buffer semiconductor layer 102, the AlGaAs electron supplying layer 103, the channel layer 104, the AlGsAs electron supplying layer 105, the InGaP etching stop layer 106 and the GaAs contact layer 107 are sequentially formed on the semi-insulating GaAs substrate 101. Thereafter, by using a photoresist or the like as a mask, parts of the GaAs contact layer 107 are selectively removed by etching with a sulfuric acid-contained etchant while the InGaP etching stop layer 106 as the underlayer is left unetched.

Subsequently, parts of the InGaP etching stop layer 106 are selectively removed by etching with a hydrochloric acid-contained etchant while the AlGaAs electron supplying layer 105 as the underlayer is left unetched. Thereby, the recessed portion is formed. Thereafter, the gate electrode 109 is provided inside the recessed portion. This introduction of the InGaP etching stop layer 106 makes it possible to form the recessed portion with a better controllability in the depth direction by use of the wet-etching techniques. As a result, this makes it possible to reduce variation in the characteristics of the manufactured FET, and to accordingly secure higher yields.

It should be noted that, in addition to Patent Document 1, Japanese Patent Application Laid-open Publication No. Hei. 10-270467 and Young, Q. et. al, Proceedings of International Conference on Compound Semiconductor (Sep. 8-11, 1997), pp. 95-98 (hereinafter referred to as “Patent Document 2”) are enumerated as documents on prior art concerning the present invention.

In the case of the structure shown in FIG. 1, a interfacial layer such as an AlGaAsP layer is produced in the interface between the AlGaAs electron supplying layer 105 and the InGaP etching stop layer 106, as pointed out by Patent Document 2. This takes place due to the substitution of As with P. Specifically, while a P-containing semiconductor is being grown on the AlGaAs layer, P enters AlGaAs due to a strong bonding force between Al and P, and thus the interfacial layer is formed.

Like the InGaP layer, usually, a crystal containing only P as a V group element can be removed by use of an etchant containing hydrochloric acid or the like. Like the AlGaAsP layer, however, a crystal containing both As and P as V group elements cannot be removed by use of an etchant containing hydrochloric acid. As a result, the AlGaAsP interfacial layer remains on the AlGaAs electron supplying layer 105 even after parts of the InGaP etching stop layer are removed. It is difficult to selectively remove only this AlGaAsP layer while the AlGaAs layer as the underlayer is left unetched. In addition, layers each containing P are easy to be oxidized. For this reason, if the gate electrode 109 is formed on the AlGaAsP layer, this formation deteriorates the Schottky characteristic. This leads to deterioration in reliability of manufactured FETs.

### SUMMARY

An FET according to the present invention is characterized by including: an electron supplying layer made of AlGaAs; an interface stabilizing layer, provided on the electron supplying layer, and not containing Al; an etching stop layer, provided on the interface stabilizing layer, and made of InGaP; and a contact layer, provided on the etching stop layer, and made of GaAs.

In this FET, the interface stabilizing layer containing no Al is provided between the AlGaAs electron supplying layer and the InGaP etching stop layer. This makes it possible to prevent an occurrence of a interfacial layer such as an AlGaAsP layer in the interface between the electron supplying layer and the etching stop layer while this FET is being manufactured. As a result, no interfacial layer remains after the etching stop layer is removed. This makes it possible to secure a better Schottky characteristic.

In addition, a method of manufacturing an FET according to the present invention is characterized by including the steps of: sequentially forming an interface stabilizing layer containing no Al, an etching stop layer made of InGaP, and a contact layer made of GaAs on an electron supplying layer made of AlGaAs; forming a first opening portion in the contact layer through etching parts of the contact layer by using the etching stop layer as an etching stopper; and forming a second opening portion connecting the first opening portion in the etching stop layer through etching parts of the etching stop layer after the first opening portion forming step.

In the case of this manufacturing method, the interface stabilizing layer containing no Al is formed between the AlGaAs electron supplying layer and the InGaP etching stop layer. This formation makes it possible to prevent an occurrence of a interfacial layer such as an AlGaAsP layer in the interface between the electron supplying layer and the etching stop layer. As a result, no interfacial layer remains after the etching stop layer is removed. This makes it possible to secure a better Schottky characteristic.

According to the present invention, an FET with a better Schottky characteristic and a method of manufacturing the same are accomplished.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view of a conventional type of FET;

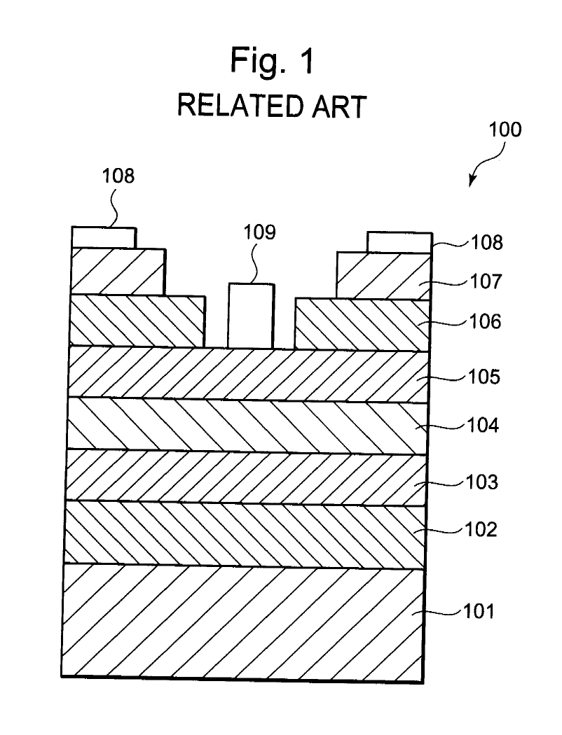

FIG. 2 is a cross-sectional view of a first embodiment of an FET according to the present invention;

FIG. 3 is a graph for explaining an effect of the embodiment;

FIGS. 4A and 4B are graphs each for explaining another effect of the embodiment;

FIG. 5 is a graph for explaining yet another effect of the embodiment;

FIG. 6 is a cross-sectional view showing a second embodiment of the FET according to the present invention; and

FIG. 7 is a cross-sectional view schematically showing what conditions appear in a vicinity of the interface between the AlGaAs electron supplying layer and the InGaP etching stop layer in the FET shown in FIG. 6.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Detailed descriptions will be provided below for the preferred embodiments of an FET and a method of manufacturing the same according to the present invention with reference to the drawings. It should be noted that the same elements are denoted by the same reference numerals while the drawings are described, and that the duplicated descriptions will be omitted.

### First Embodiment

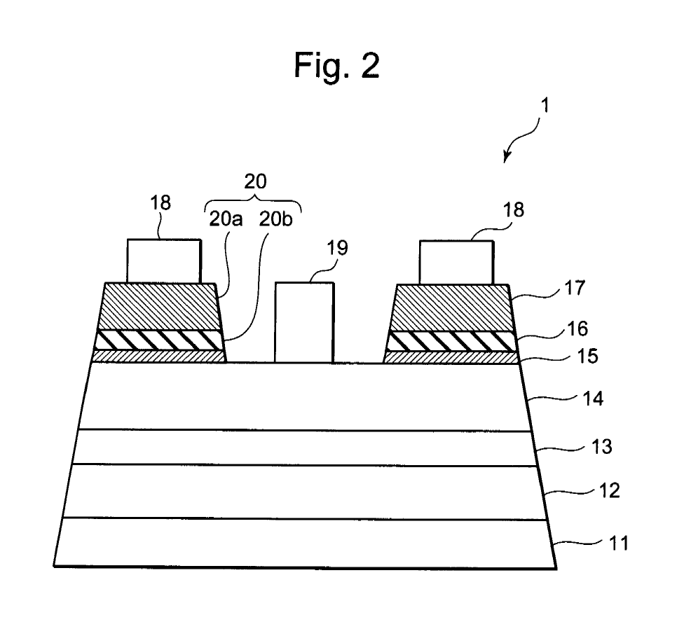

FIG. 2 is a cross-sectional view showing a first embodiment of the FET according to the present invention. The FET 1 is an GaAs heterojunction FET, which includes: an electron supplying layer 14 made of AlGaAs; an interface stabilizing layer 15, provided on the electron supplying layer 14, and not containing Al; an etching stop layer 16, providing on the interface stabilizing layer 15, and made of InGaP; and a contact layer 17, provided on the etching stop layer 16, and made of GaAs.

More specifically, a buffer layer 12 made of GaAs, a channel layer 13 made of InGaAs, the electron supplying layer 14, the interface stabilizing layer 15, the etching stop layer 16, and the contact layer 17 are sequentially formed on a semi-insulating GaAs substrate 11. In the case of the present embodiment, the interface stabilizing layer 15 is a GaAs layer. It is preferable that the thickness of the interface stabilizing layer 15 be not less than the thickness of a two-molecular layer (approximately 0.56 nm), but not more than 3 nm.

A source/drain electrode 18 is formed on the contact layer 17. In addition, a recessed portion 20 is formed in the etching stop layer 16 and the contact layer 17. The recessed portion 20 is configured of an opening portion 20a (first opening portion) formed in the contact layer 17, and an opening portion 20b (second opening portion) formed in the etching stop layer 16. It is preferable that this recessed portion 20 should reach the electron supplying layer 14 by penetrating the interface stabilizing layer 15. A gate electrode 19 is provided inside the recessed portion 20.

Descriptions will be provided for an example of a method of manufacturing the FET 1 as an embodiment of a method of manufacturing an FET according to the present invention. First of all, the buffer layer 12, the channel layer 13, the electron supplying layer 14, the interface stabilizing layer 15, the etching stop layer 16 and the contact layer 17 are sequentially formed on the GaAs substrate 11. Thereafter, parts of the contact layer 17 are etched by using the etching stop layer 16 as an etching stopper. Thereby, the opening portion 20a is formed in the contact layer 17. Subsequently, parts of the etching stop layer 16 are etched. Thereby, the opening portion 20b connecting with the opening portion 20a is formed in the etching stop layer 16. Afterward, the gate electrode 19 is provided inside the recessed portion 20 thus formed.

The opening portions 20a and 20b are formed by wet etching. It is preferable that an aqueous solution containing sulfuric acid or phosphoric acid should be used as an etchant in the step of forming the opening portion 20a, and that an aqueous solution containing hydrochloric acid should be used as an etchant in the step of forming the opening portion 20b.

Descriptions will be provided for effects of the present embodiment. In a case where, for example, the InGaP etching stop layer is grown on the AlGaAs electron supplying layer by solid source MBE (Molecular Beam Epitaxy), a interfacial layer such as an AlGaAsP takes place. A cause of this is that P is drawn into the AlGaAs layer because of a strong bonding force between Al atoms and P atoms in the uppermost surface. For the purpose of preventing the occurrence of the interfacial layer, it is accordingly important that Al and P should be prevented from being bonded with each other. With this taken into consideration, the FET 1 includes the interface stabilizing layer 15 which is provided between the electron supplying layer 14 and the etching stop layer 16. This makes it possible to prevent the occurrence of the interfacial layer in the interface between the electron supplying layer 14 and the etching stop layer 16. As a result, no interfacial layer remains after the etching stop layer 16 is removed. This makes it possible to secure a better Schottky characteristic.

The present embodiment makes it possible to prevent variation in characteristics while securing a better initial static characteristic and a higher reliability in the GaAs heterojunction FET with a recessed portion which is used as a transistor operating with a high frequency band of several GHz to tens of GHz. Accordingly, this makes it possible to cut back on costs.

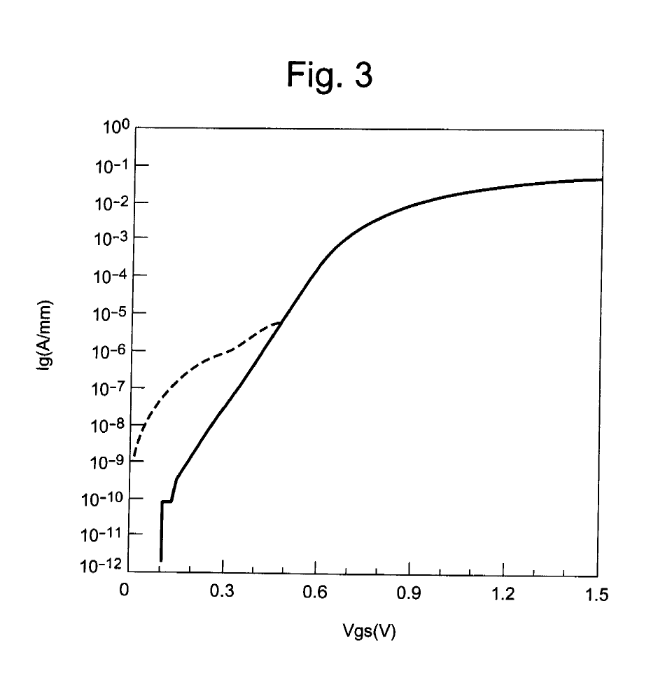

FIG. 3 is a graph showing a result of comparison between the FET 1 according to the present invention and an FET according to the prior art in terms of static characteristic. A solid line indicates a result of providing the interface stabilizing layer 15, or a result of the FET 1 according to the present invention. A broken line indicates a result of providing no interface stabilizing layer 15, or a result of the FET according to the prior art. As learned from this graph, it was proved that the FET 1 had a better Schottky characteristic. In the case of the FET according to the prior art, it is learned that a leakage current took place when the gate voltage was in a lower range because of the AlGaAsP interfacial layer remaining on the surface of the AlGaAs electron supplying layer. No other difference in static characteristic was observed between the two FETs.

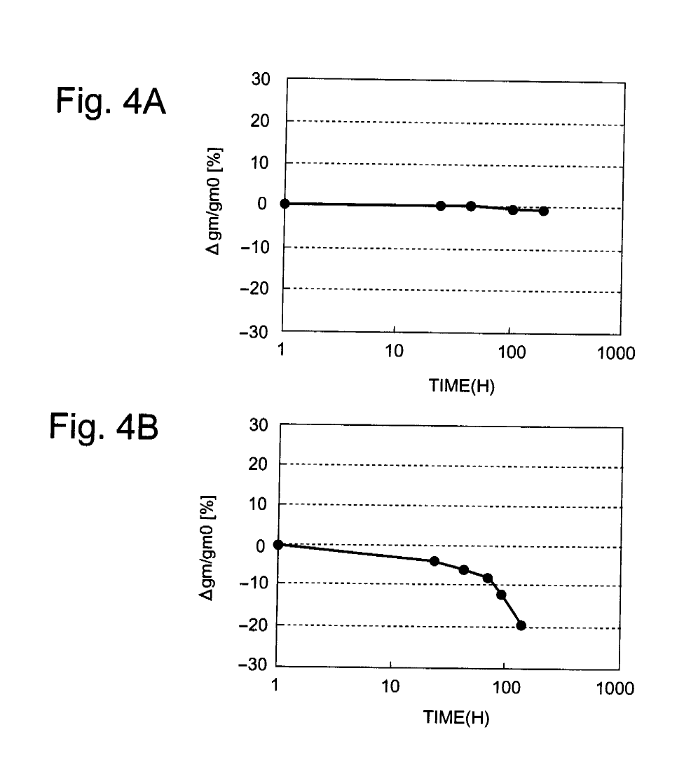

FIG. 4A is a graph showing change in characteristics which was observed when the reliability of the FET 1 according to the present embodiment was tested, and FIG. 4B is a graph showing change in characteristics which was observed when the reliability of the FET according to the prior art was tested. As learned from FIG. 4A, almost no deterioration in device characteristics of the FET 1 according to the present embodiment was observed during a high-temperature bias stress test. As learned from FIG. 4B, deterioration in device characteristics of the FET according to the prior art was observed as reflecting deterioration in the AlGaAsP interfacial layer remaining on the surface of the AlGaAs electron supplying layer.

In a case where the thickness of the interface stabilizing layer 15 is approximately equal to the thickness of a two-molecular layer, it is possible to remove the interface stabilizing layer 15 by overetching when the etching stop layer 16 is etched. For this reason, the recessed portion 20 which reaches the electron supplying layer 14 is able to be formed. In this case, the gate electrode 19 and the electron supplying layer 14 are in direct contact with each other. This makes it possible to obtain a better Schottky characteristic.

In a case where the thickness of the interface stabilizing layer 15 is more than the thickness of a two-molecular layer, it is possible to keep Al in the electron supplying layer 14 and P in the etching stop layer 16 sufficiently separated away from each other. In a case where the thickness of the interface stabilizing layer 15 is not more than 3 nm, the Schottky characteristic little deteriorates because the thickness is sufficiently thin, even if the interface stabilizing layer 15 still remains after the etching stop layer 16 is removed. Little deterioration was observed in the reliability test that was carried out subsequently.

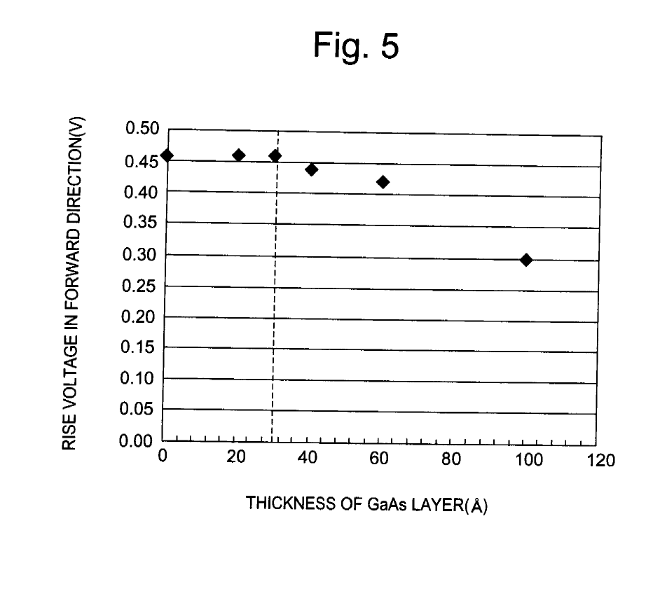

FIG. 5 is a graph showing a result of examining a relationship between rise voltages in the forward direction and thicknesses of the interface stabilizing layer 15. It was proved that little deterioration in the Schottky characteristic was observed when the thickness of the interface stabilizing layer 15 was in a range of not more than 3 nm (30 Å).

### Second Embodiment

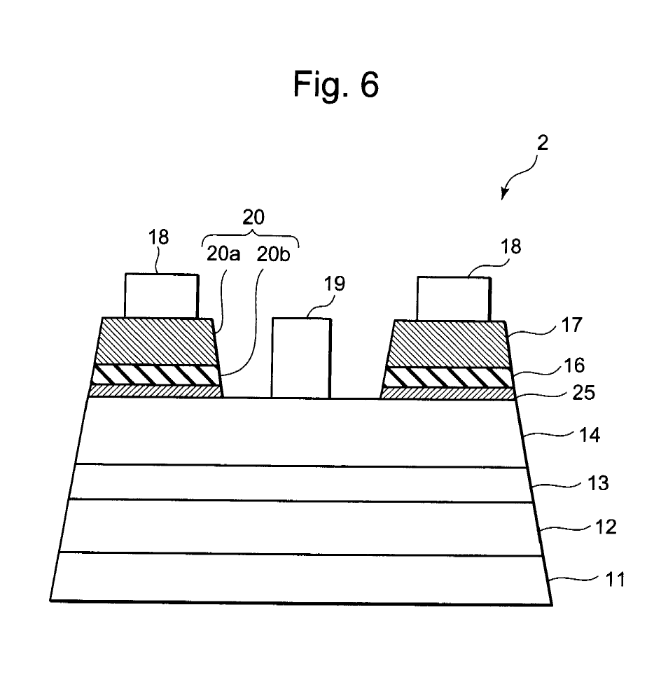

FIG. 6 is a cross-sectional view showing a second embodiment of the FET according to the present invention. In a FET 2, an InP layer is used as an interface stabilizing layer 25. It is preferable that the thickness of this interface stabilizing layer 25 should be not less than the thickness (approximately 0.56 nm) of a two-molecular layer, but not more than 3 nm in common with the interface stabilizing layer 15 in the FET 1 shown in FIG. 2. The other parts of the configuration of the FET 2 are the same as those of the FET 1. In addition, the FET 2 can be manufactured in the same manner as the FET 1 can.

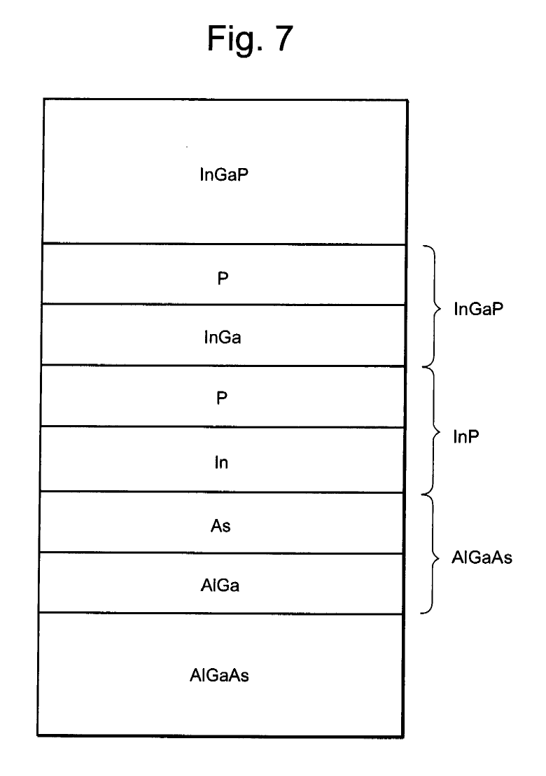

FIG. 7 is a cross-sectional view schematically showing what conditions appear in a vicinity of the interface between the AlGaAs electron supplying layer 14 and the InGaP etching stop layer 16 in the FET 2. After the AlGaAs electron supplying layer 14 is grown by solid source MBE or the like, the uppermost surface is covered with As. If In atoms are irradiated on the uppermost surface while in this condition, the As surface is covered with In, and is thus stabilized. If P is thereafter irradiated on the uppermost surface, the InAs surface blocks Al and P from being bonded with each other. This prevents P from being taken into the AlGaAs layer. This makes it possible to prevent the interfacial layer from taking place. As a result, no interfacial layer remains after the etching stop layer 16 is removed. This makes it possible to secure a better Schottky characteristic. The other effects of the FET 2 are the same as those of the FET 1.

It is apparent that the present invention is not limited to the above embodiments, but may be modified and changed without departing from the scope and spirit of the invention.

What is claimed is:

1. A field effect transistor comprising:
an electron supplying layer made of AlGaAs;
an interface stabilizing layer, provided on the electron supplying layer, and not containing Al;
an etching stop layer, provided on the interface stabilizing layer, and made of InGaP; and
a contact layer, provided on the etching stop layer, and made of GaAs.

2. The field effect transistor as recited in claim 1, wherein the thickness of the interface stabilizing layer is not less than 0.56 nm, but not more than 3 nm.

3. The field effect transistor as recited in claim 1, wherein the interface stabilizing layer is any one of a GaAs layer and an InP layer.

4. The field effect transistor as recited in claim 1, comprising a recessed portion formed in the etching stop layer and the contact layer,
wherein a gate electrode is provided inside the recessed portion.

5. The field effect transistor as recited in claim 4, wherein the recessed portion reaches the electron supplying layer by penetrating the interface stabilizing layer.

6. A method of manufacturing a field effect transistor, comprising the steps of:
sequentially forming an interface stabilizing layer containing no Al, an etching stop layer made of InGaP, and a contact layer made of GaAs on an electron supplying layer made of AlGaAs;
forming a first opening portion in the contact layer by using the etching stop layer as an etching stopper; and
after the step of forming the first opening portion, forming a second opening portion connecting with the first opening portion in the etching stop layer.

7. The method of manufacturing a field effect transistor are recited in claim 6, wherein
in the step of forming the first opening portion, an aqueous solution containing any one of sulfuric acid and phosphoric acid is used as an etchant, and
in the step of forming the second opening portion, an aqueous solution containing hydrochloric acid is used as an etchant.

8. The method of manufacturing a field effect transistor as recited in claim 6, comprising a step of forming a gate electrode inside a recessed portion configured of the first and second openings.
